(19) United States
(12) Patent Application Publication
(10) Pub. No.: US 2006/0157733 A1
(43) Pub. Date: Jul. 20, 2006

(54) Complex oxides for use in semiconductor devices and related methods

(76) Inventors: Gerald Lucovsky, Cary, NC (US); Darrell Schlom, State College, PA (US)

Correspondence Address: MYERS BIGEL SIBLEY & SAJOVEC, PO BOX 37428, RALEIGH, NC, 27627, US

(21) Appl. No.: 10/560,488

(22) PCT Filed: Jun. 10, 2004
(86) PCT No.: PCT/US04/18863

§ 371 Date: Dec. 12, 2005

Related U.S. Application Data
(60) Provisional application No. 60/478,586, filed on Jun. 13, 2003.

(51) Int. Cl. H01L 31/0328; H01L 21/336

(52) U.S. Cl. 257/192; 257/194; 438/285; 257/E29.246

(57) ABSTRACT

A semiconductor device includes a semiconductor substrate, a first oxide layer on the semiconductor substrate including an element from the semiconductor substrate, and a second oxide layer on the first oxide layer opposite the semiconductor substrate. The second oxide layer includes a stoichiometric, single-phase complex oxide represented by the formula:
AₕBⱼOₖ, or equivalently (AₘOₙ)ₐ(B_{q}Oᵣ)_{b}
in which the elemental oxide components, (AₘOₙ) and (B_{q}Oᵣ) are combined so that h=j or, equivalently, ma=bq, and a, b, h, j, k, m, n, q and r are non-zero integers; and wherein: A is an element of the lanthanide rare earth elements of the periodic table or the trivalent elements from cerium to lutetium; and B is an element of the transition metal elements of groups IIIB, IVB or VB of the periodic table.

### FIELD OF THE INVENTION

The invention generally relates to oxides that may be used in conjunction with integrated circuit devices, e.g., field effect transistors and high electron mobility transistors, as well as other devices including photovoltaics, and methods of making the same.

### BACKGROUND OF THE INVENTION

Insulated gate field effect transistors (IGFETs) typically include a channel region in which current is controlled through the application of an electrical bias to a gate electrode that is separated from the channel region by a thin insulating film or gate dielectric. Current through the channel is supplied and collected by source and drain contacts, respectively, to the channel region. As semiconductor devices become increasingly miniaturized, gate dielectrics having a reduced equivalent oxide thickness (EOT) may be desirable. For example, the Semiconductor Industry Association (SIA) National Technology Roadmap for Semiconductors (NTRS) has projected that gate dielectrics with an EOT below 1 nm may be desirable for uses such as in advanced complementary metal-semiconductor oxide field-effect transistor (CMOS FET) devices having channel lengths scaled to below 50 nm. However, reduced EOT dielectrics may exhibit tunneling and current leakage. For example, tunneling of conventional materials such as SiO₂ may exceed 1-5 A/cm² at applied gate bias levels of about 1 V above threshold for an EOT of less than 1.4 nm.

One possible approach for decreasing EOT without increasing direct tunneling leakage current may involve substituting alternative oxides with dielectric constants (K) that could exceed that of SiO₂. Silicon dioxide has a dielectric constant of approximately 3.9. For example, it may be desirable to obtain oxides with dielectric constants ranging from approximately 10 to more than 30. However, dielectric materials with higher vales of K generally tend to have relatively small band gaps, which can also contribute to undesirable tunneling leakage current in semiconductor devices despite a relatively high dielectric constant.

Silicon nitride and silicon oxynitride alloys have been proposed as dielectric materials. Silicon nitride and silicone oxynitride alloys have dielectric constants of approximately 7.6 and 5.5 to 6.0 respectively. For example, C. J. Parker, G. Lucovsky and J. R. Hauser, IEEE Electron. Device Lett. (1998); Y. Wu and G. Lucovsky, IEEE Electron. Device Lett. (1998); and H. Yang and G. Lucovsky, IEDM Digest, (1999) propose oxide-nitride and oxide-oxynitride alloy stacked dielectrics with EOT projected to be greater than about 1.1 nm before tunneling leakage at approximately 1 V is increased above 1-5 A/cm². The preparation of these stacked dielectrics proposes two 300° C. remote plasma process steps: i) plasma-assisted oxidation to form Si—SiO₂ interface layers ranging in thickness from about 0.5 to 0.6 nm, and ii) remote plasma-enhanced chemical vapor deposition (RPECVD) to deposit either a nitride or an oxynitride (e.g., (SiO₂)ₓ(Si₃N₄)₁₋ₓ with x˜0.5) dielectric film in the dielectric stack. After deposition, a low thermal budget, e.g., 30 second, 900° C., rapid thermal anneal (RTA) has been proposed in an attempt to achieve chemical and structural relaxation. This RTA may promote optimized performance in IGFET devices [G. Lucovsky, A. Banerjee, B. Hinds, G. Claflin, K. Koh and H. Yang, J. Vac. Sci. Technol. B15, 1074 (1997)]. Stacked nitride and oxynitride gate dielectrics may display improved performance and reliability with respect to thermally-grown oxides of the same EOT. Nonetheless, these gate dielectrics typically have EOT of greater than 1.1 nm in order to attempt to maintain direct tunneling leakage below 1 A/cm². The nitride and oxynitride layers of these devices may be sufficiently thick to minimize or stop boron out-diffusion out of p⁺ polycrystalline Si gate electrodes in the p-channel IGFETs [Y. Wu, et al., Vac. Sci. Technol. B17 1813 (1999)].

Other high-K dielectrics have been proposed (e.g., a K greater than 8) including TiO₂ [J. Yan, D. C. Gilmer, S. A. Campbell, W. L. Gladfelter and P. G. Schmid, J. Vac. Sci. Technol. B 14, 1706 (1996).], Ta₂O₅ [H. Shinrike and M. Nakata, IEEE Trans. on Elec. Devices 38, 544 (1991)], Al₂O₃ [L. Manchanda, W. H. Lee, J. E. Bower, F. H. Baumann, W. L. Brown, et al., IEDM Tech. Dig., p. 605 (1998)], ZrO₂, [R. B. van Dover, et al., IEEE Electron Device Lett., 19, 329, (1998)] and Zr(Hf)O₂—SiO₂ (also designated as Zr(Hf)-silicates; see van Dover et al.). These materials may not demonstrate the targeted goals of capacitance with decreased tunneling or leakage currents that may be desirable for silicon CMOS devices. For example, these materials may exhibit tunneling or leakage currents in CMOS devices with EOT less than 1 nm. The performance of the materials may be limited due to the oxidation of the silicon substrate that can occur during thermal chemical vapor deposition (CVD) or during post-deposition processing, such as, for example, thermal anneals, to fully oxidize the deposited thin films.

Another high-K dielectric is non-crystalline Al₂O₃. The dielectric constant of Al₂O₃ is generally about nine or less, but Al₂O₃ has a band gap of more than 7 eV and conduction and valence band offset energies greater than 2 eV. However, because of its increased bond-ionicity with respect to SiO₂ (Lucovsky, JVST), non-crystalline Al₂O₃ dielectric films may display a high value of interfacial fixed negative charge, e.g., greater than 10¹² cm⁻², as compared to less than 10¹¹ cm⁻² for SiO₂ dielectrics, at interfaces with Si, or at interfaces with superficially thin (<0.5-1.0 nm) non-crystalline SiO₂ in contact with Si. This high value of fixed charge has been correlated with electron and hole mobility degradation in the channel of IGFET devices and can potentially contribute to a reduction in the dimensionally-scaled drive current by factors of two or more. Accordingly, the gains in device capacitance derived from the increased value of K may be diminished.

Other relatively high-K materials include transition metal and rare earth elemental oxides. These dielectrics may be qualitatively different than non-crystalline SiO₂ and Al₂O₃ in as much as the lowest conduction band states may be associated with localized atomic d-states of the respectively transition metal and rare earth atoms in contrast to the delocalized or extended s-state conduction band edge states of non-crystalline SiO₂, Al₂O₃ and the like. A comparison of an electronic structure diagram of the conduction band edge states of non-crystalline SiO₂ and a metal or rare earth oxide is shown in FIG. 1. Excitations to these states may show strong final state effects. Moreover, the lowest conduction band states may display a linear scaling of the optical band gap (i.e., the energy associated with the generation of a electron-hole pair created by absorption of a photon) with the atomic d-state energy in a configuration appropriate to bonding to oxygen atoms in a dielectric. For dielectric applications, this configuration is generally designated as S²dⁿ⁻², where n is total number of valence electrons. For example, n is 3 for the group IIIB transition metal atoms, and the lanthanide rare earth atoms, 4 for the group IVB transition metal atoms, and 5 for the group VB transition metal atoms. This scaling is displayed in FIG. 2, where specific transition metal and rare earth oxides have been identified in the diagram. FIG. 2 also includes estimated and/or measured values of the conduction band offset energies relative to Si. As noted above, there is also an empirical relationship between the band gap, E_{g}, and the dielectric constant, K, such that E_{g} generally decreases as K increases. The scaling in FIG. 1 may be validated experimentally. Due to these properties, several high-K thin film dielectrics, including TiO₂, Nb₂O₃ and Ta₂O₃ may perform poorly if incorporated into silicon MOSFET devices.

There may be other problems in the application of elemental oxides, such as the transition metal oxides, ZrO₂, HfO₂, Y₂O₃, La₂O₃, and the rare earth oxides (including Gd₂O₃ and the like), into aggressively scale miniaturized MOSFET devices. The various problems that can be experienced include i) high values of interfacial fixed charge that are generally positive ii) ion and atom transport, iii) high reactivity with ambient gases, giving rise to incorporation or water or hydroxyl groups, and iv) lower than anticipated tunneling currents due to reduced electron masses associated with the electronic structure, e.g., because the lowest conduction band has d-state properties. This last effect may be more apparent in transition metal oxides than in rare earth oxides. Other process integration issues may relate to the combined effects of their hydrophyllic nature and oxygen ion transport that can promote changes in interface bonding during post-deposition thermal process steps, including dopant activation of atoms in source and drain contacts to the channel in a MOSFET device.

Other high-K dielectric materials include non-crystalline silicate and aluminate alloys, which are generally non-stoichiometric and may not correspond to the composition of a particular crystalline phase. For example, hafnium silicate and aluminate alloys in the alloy composition range from ˜25% to at most 50% HfO₂ have been proposed, as well as Zr silicate and aluminate alloys. Hafnium silicates may have reduced reactivity with Si substrates and the like. However, one drawback for both group IVB silicates may be their thermal stability against chemical phase separation into ZrO₂ or HfO₂, and a relatively low content silicate alloy (less than 10% ZrO₂ or HfO₂ as determined by the concentration of the eutectic in the equilibrium phase diagram), and crystallization of the ZrO₂ or HfO₂ phase. Thermal instability generally occurs at temperatures of ˜900° C. for low ZrO₂ content Zr silicate alloys, and at temperature ˜1000° C. for low HfO₂ content Hf silicates. Less is understood about chemical phase separation in aluminate alloys; however, there is some evidence for crystallization in Hf aluminate alloys. Decreases in K upon alloying with either SiO₂ or Al₂O₃ may be significant. For example, the Zr and Hf silicate alloys that display the greatest amount of thermal stability against crystallization have dielectric constants less than 15. Nonetheless, they display reduced direct tunneling with respect to their respective end-member elemental oxides because of mitigating factors, such as the tunneling effective mass, that can increase as the transition metal oxide fraction increases. The precursor bonding states that drive the chemical phase separation can be a function of the degree of rigidity or over-constrained bonding in the non-crystalline alloy, particularly in the composition range of about 25 to 50% ZrO₂ or HfO₂. The increased rigidity of these alloys relative to non-crystalline SiO₂, and nano- or micro-crystalline ZrO₂ or HfO₂, is the driving force for the chemical separation. The separated state is lower in energy, but also has a significantly reduced dielectric constant that renders phase separated dielectrics not useful for certain applications. In addition, the rigidity of these low ZrO₂/HfO₂ content silicate films may result in i) defects in the bulk of the film that cannot be compensated by hydrogen or deuterium, and leads to electron injection and trapping under biased conditions, and also ii) defect formation at the semiconductor dielectric interfaces, e.g., silicon atom dangling bonds in the strained silicon in contact with the dielectric film, and/or a superficially thin region with predominantly Si—O bonding.

Other potential problems encountered with various high-K dielectrics may relate to: (1) the crystallization of the deposited films during either deposition or post-deposition processing, (2) the low dielectric constants of the bulk films that may be insufficient to meet the targeted goals, and (3) the formation of interfacial silicon oxides, or low content silicon oxide alloys (e.g., silicates) that may limit the attainable effective values of the K for the resulting stacked dielectric structure. For example, it is believed that oxidation of the silicon substrate during deposition or post-deposition processing may mitigate many of the gains of high-K layers with respect to achievable capacitance, whereas crystallization has the potential to open up alternative conduction pathways, the possibility of anisotropic dielectric constant behavior, and the potential to produce surface roughening.

The formation of interfacial silicide bonds may result in undesirable interfacial defects. Such defects may occur in the form of fixed positive charge or interface traps. Thus, it may be desirable to employ a thin dielectric interface layer of SiO₂ between the dielectric layer and the silicon substrate. Utilizing such interfacial layers with known insulating film dielectrics, however, may be disadvantageous in that they may limit the dielectric stacks from having sufficient capacitance to meet the ever-increasing scaling demands of CMOS devices. Additionally, this use of interfacial layers may also limit the incorporation of high-K oxides into devices that employ semiconductor substrates other than silicon such as, for example, silicon carbide, gallium nitride and compound semiconductors such as SiC, GaN, (Al,Ga)N, GaAs, (Al,Ga)As, (In,Ga)As, GaSb, (Al,Ga)Sb, (In,Ga)Sb, as well as nitride, arsenide and antimonide quaternary III-V alloys.

### SUMMARY

According to embodiments of the present invention, a semiconductor device includes a semiconductor substrate, a first oxide layer on the semiconductor substrate including an element from the semiconductor substrate, and a second oxide layer on the first oxide layer opposite the semiconductor substrate. The second oxide layer includes a stoichiometric, single-phase complex oxide represented by the formula:
AₕBⱼOₖ, or equivalently (AₘOₙ)ₐ(B_{q}Oᵣ)_{b}

in which the elemental oxide components, (AₘOₙ) and (B_{q}Oᵣ) are combined so that h=j or, equivalently, ma=bq, and a, b, h, j, k, m, n, q and r are non-zero integers; and

wherein:

A is an element of the lanthanide rare earth elements of the periodic table or the trivalent elements from cerium to lutetium; and

B is an element of the transition metal elements of groups IIIB, IVB or VB of the periodic table.

The second oxide layer may have a thickness of less than 15 nm, a band gap of greater than about 5.5 eV, a conduction band offset energy of greater than 1.5 eV, and/or an equivalent oxide thickness (EOT) of about 0.5 to about 1.6 nm. In certain embodiments, B is an element with 3d, 4d or 5d electrons available for bonding to oxygen and A is an element in which one 5d electron is available for bonding. B may be scandium, titanium, tantalum or niobium. A may be trivalent gadolinum, praseodynium or lutetium. A can be cerium, nedoymnium, promethium, samarium, europium, terbium, dysprosium, holmium, erbium, thulium, or ytterbium.

The first oxide layer can include a nitrided silicon dioxide and/or may contribute less than about 0.5 nm of oxide-equivalent capacitance to said field effect transistor.

Devices according to embodiments of the present invention include a field effect transistor, a photovoltaic device, and/or a high electron mobility transistor.

According to further embodiments of the present invention, methods of forming a semiconductor device include providing a semiconductor substrate and forming a first oxide layer on the semiconductor substrate. A second oxide layer is formed on the first oxide layer opposite the semiconductor substrate. The second oxide layer comprising a stoichiometric, single-phase, complex oxide represented by the formula described above.

Methods according to embodiments of the present invention can include exposing the substrate to one or more gaseous sources comprising elements A, B, and oxygen such that one or more gaseous sources react to form the second oxide layer. The one or more gaseous sources can include an amount of oxygen sufficient to substantially oxidize elements A and B.

The second oxide layer can be formed by a remote plasma-enhanced chemical vapor deposition process. A gaseous source comprising oxygen and a rare-gas element can be exposed to radio-frequency plasma-excitation or microwave frequency plasma-excitation. The gaseous source comprising oxygen and a rare-gas element can be combined with a gaseous source comprising element A and element B. The substrate can be exposed to the combined gaseous source. The second oxide layer can be formed by an atomic layer absorption process.

### BRIEF DESCRIPTION OF THE DRAWINGS

FIG. 1 is an electronic structure diagram of band edge electronic states in SiO₂, which may be representative of network non-crystalline dielectrics, and a thin film transition metal or rare earth oxide, which may be representative of a large class of high-K elemental oxide dielectrics;

FIG. 2 is a graph of the band gap and conduction band offset energy scaling for transition metal oxides as a function of the energy of their atomic highest occupied atomic d-state in the s²dⁿ⁻² configuration;

FIGS. 3a and 3b are cross sectional side views of a field effect transistor comprising a thin film oxide gate insulating layer according to embodiments of the present invention;

FIGS. 4a and 4b are cross sectional side views of a photovoltaic device comprising a thin film oxide passivation layer according to embodiments of the present invention;

FIGS. 5a and 5b are cross sectional side views of a high electron mobility transistor comprising a thin film oxide passivation layer according to embodiments of the present invention;

FIGS. 6a to 6d are schematic illustrations of local bonding arrangements of the constituent atoms, including band edge electronic structures: FIG. 6a illustrates silicon and aluminum oxides, SiO₂ and Al₂O₃, respectively; FIG. 6b illustrates elemental transition metal or lanthanide rare earth oxides; FIG. 6c illustrates Tm or Re silicate or aluminate alloys, and FIG. 6d illustrates complex oxides; and

FIG. 7 is a schematic comparison of the band edge electronic structure non-crystalline Tm or Re elemental oxides and non-crystalline complex oxides according to embodiments of the present invention.

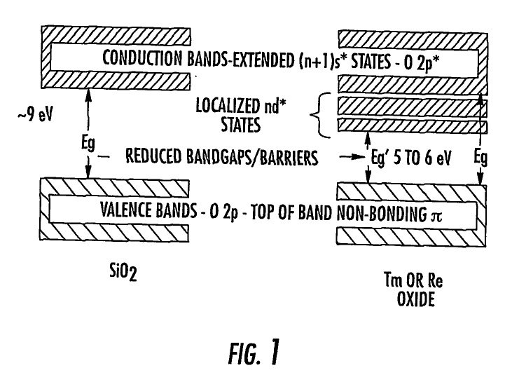

### DETAILED DESCRIPTION OF EMBODIMENTS OF THE INVENTION

The present invention now will be described more fully hereinafter with reference to the accompanying drawings and examples, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will also be understood that when a layer is referred to as being “on” another layer or substrate, it can be directly on the other layer or substrate, or intervening layers may also be present.

According to embodiments of the present invention, oxides are provided that may be represented by the formula (I):
(AₘOₙ)ₐ(B_{q}Oᵣ)_{b} or equivalently AₕBⱼOₖ, (I)
in which the elemental oxide components, AₘOₙ and B_{q}Oᵣ, are combined so that h=j or, equivalently ma=bq. The variables a, b, h, j, k, m, n, q and r are non-zero integers, and A is a lanthanide rare earth atom and B is a first, second or third row transition metal from group IIIB, IVB or VB, respectively. Oxides according to embodiments of the present invention include stoichiometric, single-phase, complex oxides according to formula (I). It should be understood that (AₘOₙ)ₐ(B_{q}Oᵣ)_{b} or AₕBⱼOₖ are equivalent representations of stoichiometric formulations according to embodiments of the present invention and may be used interchangeably.

As used herein, the lanthanide rare earth series is defined as it is in F. A. Cotton and G. Wilkenson, Advanced Inorganic Chemistry, A Comprehensive Text, 3rd Edition, (Interscience Publishers, New York, 1972), from Ce atomic number 58 with one 4f electron, to Lu, atomic number 71 with a complete shell of ten 4f electrons. Accordingly, group IIIB elements are in order of increasing atomic number, Sc (atomic number 21), Y (atomic number 39), and La (atomic number 57).

Referring to formula (I) and without wishing to be bound by theory, atoms A and B may have different respective atomic d-state energies in the s²dⁿ⁻² configuration identified above. Examples of thin film complex oxides that are described by formula (I) include, GdScO₃, Dy₂Ti₂O₇, SmNbO₈, where Gd, Dy, and Sm are the A atoms are from the lanthanide rare earth group, and Sc, Ti and Nb are first row transition atoms from groups IIIB, IVB and VB, respectively. Accordingly, bonding arrangements may be specified at the atomic scale in stoichiometric thin film complex oxides according to formula (I).

Oxides according to formula (I) may exhibit improved features with respect to the following exemplary characteristics: i) electronic and optical band gaps, ii) conduction band offset energies with respect to semiconductors, including Si, Si, Ge alloys, Ge, as well as compound semiconductors including SiC, GaN, (Al,Ga)N, GaAs, (Al,Ga)As, (In,Ga)As, GaSb, (Al,Ga)Sb, (In,Ga)Sb and the like, as well nitride, arsenide and antimonide quaternary III-V alloys, and/or iii) static dielectric constants. Separate and independent control of these features may be accomplished, for example, through materials engineering at the atomic scale, and, in particular, through the interactions between the atomic d-states of the respective transition metal and rare earth atoms through bonding to a common bridging oxygen atom of the intrinsic microscopic bonding structures of the thin film, stoichiometric complex oxides described herein. Thin film, stoichiometric complex oxides according to formula (I) may be integrated into metal-oxide-semiconductor (MOS) devices and can provide improved performance as compared to their constituent elemental oxides and/or pseudo-binary alloys of their constituent oxides with network forming oxides such as non-crystalline SiO₂, Al₂O₃ and the like. The complex oxides according to formula (I) can also provide surface passivation layers for photovoltaic devices and/or buried channel high electron mobility transistors (HEMTs).

Complex oxides, including group IIIB oxides such Y₂O₃ and La₂O₃ in combination with lanthanide rare earth oxides such as Gd₂O₃ and the like, may have different, potentially advantageous, properties when compared to their constituent elemental oxides. The complex oxides can be less hydroscopic in combination than their respective constituent oxides, which can result in advantages in processing complexity. This may be achieved while maintaining large band gaps, e.g., greater than about 5.5 eV and large conduction band offset energies, e.g., greater than 1.5 eV.

According to embodiments of the present invention, thin film oxides according to formula (I) are provided as passivation or active layers in various electronic, photoelectronic, and/or microelectronic devices. For example, thin film oxides according to formula (I) may be used as gate dielectrics that are a constituent of microelectronic devices such as insulating gate field effect transistors (IGFETs), that include crystalline, polycrystalline, and amorphous (non-crystaline) semiconductors. In still further embodiments according to the present invention, thin film surface passivation layer dielectric materials are provided for other devices including photovoltaic devices, such as radiation detectors and solar energy converters, and buried channel field effect transistors, such as HEMTs. Thin film dielectrics according to embodiments of the present invention may be generally less than 15 nm thick, and may be non-crystalline. As used herein, “non-crystalline” and “amorphous” are used interchangeably to refer to substances in which the atoms do not generally exhibit crystallinity on any size scale, for example, as determined by conventional x-ray, electron or neutron diffraction, and electron imaging techniques, including, but not limited to high resolution transmission electron micrographs, in either the bright or dark field measurement configurations, or alternatively, and in both bright and dark field images of the same portion of the dielectric film. Moreover, high resolution analytical techniques that are incorporated in the scanning transmission electron microscopes can be used to establish the single-phase nature of dielectrics.

In some embodiments according to the present invention, thin film oxides according to formula (I) may be employed in field effect transistors as thin gate insulating layers having high dielectric constants. The thin film oxides potentially allow for field effect transistors employing the same to possess gate capacitance in excess of what may be achieved with conventional insulating layers and with reduced direct tunneling currents. As an example, the direct tunneling currents may be reduced by one order of magnitude, two to three orders of magnitude, or more, such as from levels in excess of 1 A/cm² for an EOT of approximately 0.5 to 1.6 nm.

Thin film dielectrics including oxides according to formula (I) may be provided with high band gaps (E_{g}), e.g., greater than 5 eV, and large conduction band offset energies in comparison to conventional semiconductor materials such as crystalline silicon, e.g., greater than at least about 1 eV or about 1.5 eV and above. Dielectric materials according to Formula (I) may be used in i) metal-oxide semiconductor field-effect transistors (MOSFETs) or Si IGFETs, as well as ii) thin film transistors (TFTs), which include IGFETs in which all of the constituent layers are formed by thin film deposition techniques. Gate dielectrics according to formula (I) for silicon MOSFETs may have significantly higher dielectric constant (K) than non-crystalline (or, equivalently, amorphous) SiO₂ (K=3.9) to enable the gate dielectric to reach an electrical equivalent of an SiO₂ layer, generally designated as the equivalent oxide thickness or EOT, with a physical thickness, tₒₓ, of less than about 10 Å with a substantially thicker film in which the physical thickness is increased by the dielectric constant ratio (See The International Technology Roadmap for Semiconductors: 1999 (Semiconductor Industry Association, San Jose, Calif., 1999), pp. 105-141. and G. D. Wilk, R. M. Wallace, and J. M. Anthony, “High K Gate Dielectrics: Current Status and Materials Properties Considerations,” J. Appl. Phys. 89 (2001) 5243-5275.) Moreover, gate dielectrics may be provided having a relatively large band gap of about 4 electron volts (eV), about 5 eV or more, and large band offset energies with respect to the conduction and valence bands of Si, ΔE_{c} and ΔEᵥ, respectively, at least ˜1 eV or more than 1.5 eV in order to provide sufficiently low gate leakage.

The oxides according to formula (I) may be used in field effect transistors, including insulating gate field effect transistors (IGFETs), metal-oxide-semiconductor field effect transistors (MOSFETs) and thin film transistors (TFTs). For example, the gate insulating layers of such devices can include the thin oxides represented by the formula (I).

Methods of fabricating devices described herein can include delivering gaseous sources comprising element A, gaseous sources comprising element B, and gaseous sources comprising oxygen on substrates such that the gaseous sources comprising element A, the gaseous sources comprising element B, and the gaseous sources comprising oxygen react to form the a desired complex oxide. The elements A and B are delivered in amounts necessary and sufficient for achieving chemical stoichiometry, e.g., equal concentrations of A and B atoms in the resulting thin films. The gaseous sources comprising oxygen can contain a sufficient amount of chemically active oxygen such that the elements A and B are completely oxidized. For example, the delivery of the gases may be carried out as a deposition. Various gaseous sources comprising element A and gaseous sources comprising element B may be employed. Examples of gaseous sources comprising element A and gaseous sources comprising element B include, but are not limited to, alkoxide compounds, organo-metallic compounds, inorganic compounds, and mixtures thereof. The alkoxide compound may be selected from the group consisting of an ethoxide, a propoxide, and a butoxide. Other gaseous sources comprising element A and gaseous sources comprising element B can be used, such as organo-metallic source gases, including those that are capable of producing the desired binary oxides (e.g., diketonates) along with other organo-metallics that contain metal-oxygen bonds. Other inorganic sources of elements A and B can be employed such as halides and nitrates. The gaseous sources comprising element A and/or element B can be derived through the evaporation of respective liquid sources comprising these elements, particularly in embodiments in which the deposition involves a physical deposition or a plasma chemical vapor deposition process.

A number of sources of oxygen may be employed. Exemplary sources of oxygen include, but are not limited to, oxygen atoms, oxygen ions, oxygen metastables, oxygen molecular ions, oxygen molecular metastables, compound oxygen molecular ions, compound oxygen metastables, compound oxygen radicals, and mixtures thereof. Compounds that can be employed in the gaseous sources include, but are not limited to, O₂, N₂O, and mixtures thereof. The formation of thin film complex oxides may take place in non-equilibrium chemical environments.

The gaseous sources comprising element A, element B, and oxygen may further comprise other components such as, for example, inert gases (e.g., argon (Ar) helium (He), or other noble gases, as well as mixtures thereof).

A number of deposition techniques can be used in forming thin film oxides. Exemplary techniques include, but are not limited to, a laser-assisted chemical vapor deposition, a direct or remote plasma assisted chemical vapor deposition, a electron cyclotron resonance chemical vapor deposition, a reactive physical vapor deposition and an atomic layer deposition. For example, a remote plasma assisted chemical deposition (REPCVD) can be employed. Various reactive physical vapor depositions can be used such as, for example, a thermal evaporation, an electron beam evaporation, a parallel plate radio frequency (rf) sputtering, a direct current (dc) sputtering, a radio frequency (rf) magnetron sputtering, and a direct current (dc) magnetron sputtering. A reactive physical vapor deposition may also occur in the form of an atomic layer absorption process.

Fabrication of thin films according to embodiments of the invention may be carried out under any number of temperature and pressure conditions. Various fabrication steps may be carried out at a temperature from about 250° C. to about 400° C. and or at pressure conditions from about 200 milli-Torr to about 500 milli-Torr.

Conventional equipment may be used to fabricate complex oxides, including, for example, a suitable reactor (e.g., reaction chamber or vessel). For example, alkoxide liquids comprising elements A and B may be injected into a reactor downstream from a remote radio-frequency excited plasma. The alkoxides may be liquids at room temperature, but at the temperature range employed in the reactor have sufficient levels of vapor to be transported into the reactor. A microwave plasma may be employed, if desired.

The gaseous source comprising oxygen may be plasma-excited, e.g., by being subjected to a radio-frequency or microwave-frequency source. The gaseous source comprising oxygen may be present in combination with an inert gas such as, for example, a rare gas such as, but not limited to, helium (He) or argon (Ar). The gaseous source comprising oxygen may be injected into the reactor at a high flow rate (e.g., 200 standard cubic centimeter per second (SCCM) through a tube with an inside diameter of about one inch) through a plasma tube at a location upstream relative to where the gaseous source comprising element A and the gaseous source comprising element B are injected into the reactor. The above injection configuration is believed to be potentially advantageous since it may minimize back-streaming of the gaseous sources comprising element A and the gaseous sources comprising element B. See e.g., G. Lucovsky, IBM J. of Res. and Devel. 43, 301 (1999).

Other techniques can be employed to provide for the deposition of the thin film comples oxide materials in a highly oxidizing environment. Exemplary techniques include, but are not limited to, embodiments involving plasma deposition, such as direct plasma deposition in conventional parallel plate reactors, triode plasma deposition, electron-cyclotron-resonance plasma deposition, laser-assisted deposition, and reactive physical vapor deposition using ozone, plasma-excited oxygen, or laser-excited oxygen.

Depending on the particular application, thin film dielectrics may be deposited onto either i) insulating substrates such as bulk fused silica and crystalline aluminum oxide (sapphire), ii) semiconductor substrates such as and not limited to Si, Ge, (Si,Ge) alloy, SiC, GaN, GaAs, GaSb, InP and other group III-V ternary and quaternary alloy substrates, ZnS, ZnSe, CdTe and group III-VI ternary and quaternary substrates, iii) semiconductor substrates with thin dielectric layers, including, but not restricted to Si with (a) nitrided SiO₂, and (b) non-crystalline La aluminate, and (b) GaN and (Ga,Al)N and the like with GaOₓ or AlOₓ, x˜1.5, and iv) metallic substrates including ordinary metals such as Al and the like, transition metals and rare earths, including Ti, Ta, Mn, Fe, Co, and Ni, and lanthanide rare earth metals, including Gd, Nd and the like.

The depositions of the complex oxides may be performed in ultra-high-vacuum compatible multi-chamber systems equipped with conventional substrate introduction load locks, and the like, but the can also be performed in reactors that incorporate sufficient purging, and gas flow dynamics to prevent chemical contamination of films or substrates. Specific vacuum compatible deposition techniques include: i) chemical vapor deposition from organo-metallic, halide or hydride transition metal and rare earth precursor molecules in the presence of strong oxidizing agents such as oxygen atoms, ozone, or other oxide molecules that are known sources of oxygen, such as, and not limited to nitrous oxide, N₂O and nitric oxide, NO, ii) plasma or photo-assisted chemical vapor deposition using the same transition metal, rare earth and oxygen atom precursor species as for chemical vapor deposition, iii) reactive physical vapor deposition from elemental or compound sources, iv) magnetron or parallel plate reactive sputtering from elemental or compound targets in an ambient that leads to formation of stoichiometric complex oxides, v) atomic layer deposition using precursor and oxidizing cycles that leads to formation of stoichiometric complex oxides.

Oxides represented by formula (I) may be used as dielectric material in integrated circuit devices, including very large scale integration (VLSI) devices including Insulated Gate Field Effect Transistors (IGFET), also referred to as MOSFET or CMOS devices. As an example, field effect transistors may be provided including gate insulators comprising non-crystalline oxides represented by the formula (I).

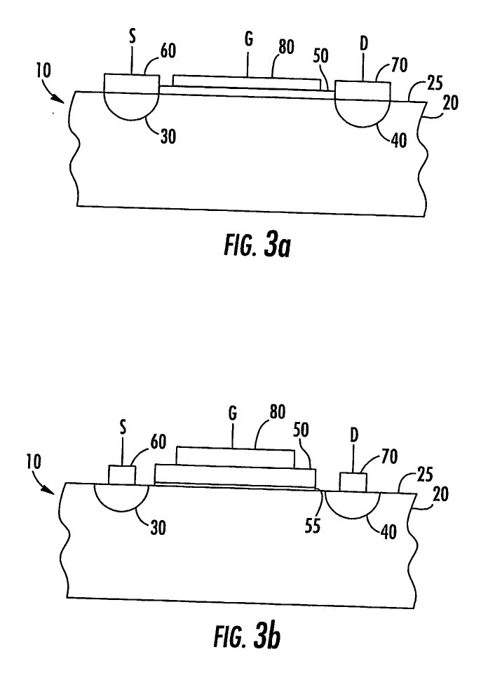

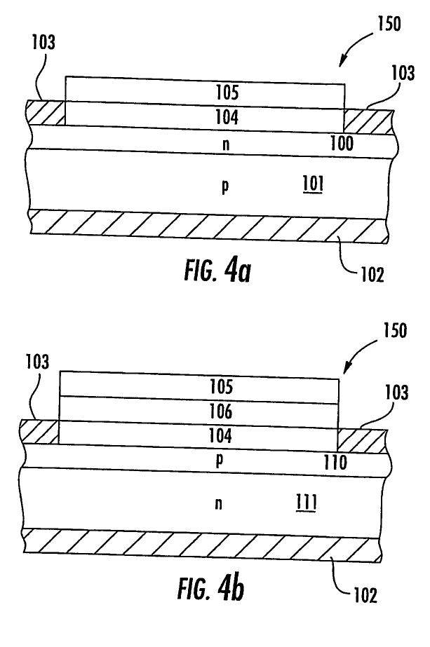

For the purposes of illustration, embodiments describing field effect transistors are set forth in FIGS. 3a and b. A field effect transistor 10 according to embodiments of the present invention is set forth in FIG. 3a. The field effect transistor 10 comprises an integrated circuit substrate 20 having a surface 25. Source and drain regions 30 and 40 respectively are present in the substrate 20 at the surface 25 in a spaced apart relationship. A gate insulating layer 50 is present on the substrate 20 at the surface 25 between the spaced apart source and drain regions, 30 and 40 respectively. The gate insulating layer 50 comprises the non-crystalline oxide represented by the formula (I) set forth herein. Source, drain, and gate contacts (60, 70, and 80 respectively) are also present and contact source and drain regions 30 and 40 and the gate insulating layer 50.

A number of materials can be employed in the integrated circuit substrate, the selection of which are known by those skilled in the art. As an example, the substrate may comprise a material selected from the group consisting of a Group III-V ternary alloy, a Group III-V quaternary alloy, a Group III-nitride alloy, and combinations thereof. Examples of Group III-V ternary alloys include, but are not limited to, (Ga,Al)As, (In,Ga)As, and combinations thereof. An example of a Group III-v quaternary alloy includes, but is not limited to, (Ga,In)(As,P). Examples of Group III-nitride alloys include, but are not limited to, (Ga,A)N, (Ga,In)N, (Al,In)N, (Ga,Al,In)N, and combinations thereof. Quaternary alloys of the above may also be employed. Additionally, group III-V antimonides, such as GaSb, III-V ternary antimonide alloys, (Al,Ga)Sb, (In,Ga)Sb, and III-v quaternary alloys, (In,Al,Ga)Sb are also included in MOSFET device substrates containing the channel region of the device.

Other examples of materials that may be employed in the integrated circuit substrate include, but are not limited to, silicon (Si), germanium (Ge), silicon carbide (SiC), gallium nitride (GaN), gallium arsenide (GaAs), as well as other compounds from Groups III and V. Combinations thereof may also be employed.

The integrated circuit substrate may encompass a number of specific substrates that are employed in devices of this type. One example of a substrate is a semiconductor-on-insulator (SOI) substrate.

The source, drain, and gate contacts may include those that are conventionally known in the art. As an example, the gate contact may be formed from polysilicon and/or metal materials.

The field effect transistor may also include other layers of materials. For example, in some embodiments (not shown), the field effect transistor may include an interfacial layer positioned between the substrate and the gate insulating layer. The interfacial layer may include an oxide, such as an oxide including an element from the semiconductor substrate. For example, the substrate may include Si or SiC and, consequently, the interfacial layer may include silicon dioxide (SiO₂). Other insulating materials may be employed. Other interfacial layers such as those comprising gallium oxide (GaO₃), aluminum oxide (Al₂O₃), or alloys thereof, may be used with compounds from Groups III and V along with their alloys. The use of the interfacial layer may be advantageous in electron-channel (n-channel) FETs and hole-channel (p-channel) FETs. The interfacial layer may contribute less than 0.5 nm of oxide-equivalent capacitance to the field effect transistor. In general, the use of an interfacial layer is believed to be advantageous in that it may: (1) prevent or minimize further oxidation of the silicon substrate during film deposition in highly oxidizing environments, (2) prevent or minimize formation of silicide bonds during the initial stages of deposition of the non-crystalline oxide materials, particularly with respect to, for example, the formation of Ta—Si bonds during the deposition of AlTaO₄.

Referring now to FIG. 3b, an additional layer 55 is depicted between the gate insulating layer 50 and the integrated circuit substrate 20 in field effect transistor 10. As shown in FIG. 3b, the additional layer is approximately one layer of interfacial bonding that includes approximately one Si—N bond per silicon substrate atom.

The field effect transistor described herein may be fabricated by methods known to a person skilled in the art. For example, a gate insulating layer may be formed by depositing a non-crystalline oxide on the substrate of the field effect transistor by employing an appropriate technique including, but not limited to, those described herein. An interfacial layer may be formed on a substrate of the field effect transistor by a suitable process such as, but not limited to, remote plasma-assisted oxidation, low pressure thermal oxidation, chemical oxidation, or photo-assisted oxidation. Thereafter, the gate insulating layer is formed by depositing the non-crystalline oxide material on the interfacial layer in the same deposition chamber used to form the interfacial layer. Alternatively, an in-line system with substrate transfer in either a high vacuum or inert environment can be used, in which chemical reactions with the interfacial layer may be minimized or prevented.

As described herein, in various embodiments, the non-crystalline oxides may be employed in field effect transistors as thin gate insulating layers having high dielectric constants. Advantageously, the non-crystalline oxides potentially allow for field effect transistors employing the same to possess gate capacitance in excess of what may possibly be achieved with conventional insulating layers with significantly reduced direct tunneling currents. As an example, the direct tunneling currents may be reduced from levels in excess of 1 A/cm².

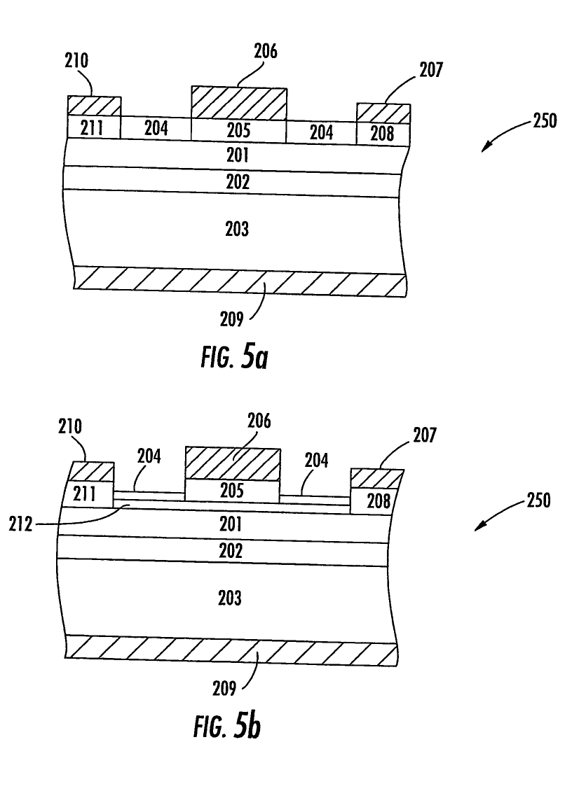

FIG. 4a illustrates a photovoltaic device 150 having a p-type semiconductor layer ohmic contact 102, a p-type layer 101, an n-type layer 100, a dielectric film surface passivation layer 104, a second dielectric layer 105 and ohmic contacts 103. A thin film stoichiometric oxide, such as an oxide according to the formula (I), is used as a surface passivation layer 104. The surface passivation layer 104 can reduce loss of photo-generated carriers in the n-type semiconductor layer 100 of the device 150. The surface passivation layer 104 and the second dielectric layer 105 can together form an anti-reflection coating. Dielectric thin films, such as oxides according to the formula (I), used as the surface passivation layer 104 may have a positive fixed charge at the interface between the n-type layer 100 and the surface passivation layer 104. This may produce a surface potential at the interface that can reduce recombination of photo-generated holes. Using the device 150 as a radiation detector under reverse bias (i.e., with a positive bias applied to the n-layer 100 through the ohmic contact 103, and the p-layer 101 maintained at ground potential through the p-type semiconductor layer ohmic contact 102) it may be necessary to have holes generated by absorption of electromagnetic radiation in the infra red, visible or near ultra-violet regions of the spectrum be transmitted into the p-layer 101 and subsequently contribute to a short circuit current in the reverse bias mode. The device 150 can also be operated an open circuit voltage or the photo-diode detector mode when the ohmic contact 103 is connected to ground through a high impedance resistive load, or a power transfer mode when the impedance of the device 150 is matched to the load resistor and no additional bias is applied. As shown in FIG. 4a, the passivation layer 104 can also serve as anti-reflection film through the incorporation of second dielectric 105, such as Si₃N₄ or SiO₂, and the like. The second dielectric 105 can be thicker than the passivation layer 104, and the thickness may be tuned to a wavelength that is within the absorption band of the semiconductor materials that comprise n-type layer 100 and p-type layer 101, as for example, Si, (Si,Ge), Ge, SiC, GaAs, (Al,Ga)As, GaN, (In,Ga)N and the like.

As illustrated in FIG. 4b, a third dielectric layer 106 has been added between the surface passivation layer 104 and the second dielectric layer 105, which are on p-type layer 110 and n-type layer 111. The conductivity types of layers 100 and 101 in FIG. 4a and layers 110 and 111 in FIG. 4b may be reversed so that the layers are complementary, e.g., such that one is doped n-type and the other is doped p-type. The various dielectric layers, including the dielectric film surface passivation layer 104, the second dielectric layer 105, and/or the third dielectric layer 106, can be thin film, stoichiometry, single-phase dielectrics, such as oxides of formula (I). Such dielectric materials generally have positive fixed charge. If the conductivity types are as shown in FIG. 4b (i.e., p-type semiconductor layer 110 and n-type semiconductor layer 111), then the third dielectric layer 106 may be inserted between the dielectric surface passivation layer 104 and the second dielectric layer 105. If the third dielectric layer 106 is Al₂O₃, and an alloy of Al₂O₃ with SiO₂, then it may have negative fixed charge at the internal interface between the dielectric surface passivation layer 104 and the third dielectric 106. This configuration may reduce electron recombination at the surface of p-type semiconductor layer 110, and can improve device performance in any one the three modes of operation described above. Moreover, the relative thicknesses of the dielectric layers including the dielectric surface passivation layer 104, the second passivation layer 105 and the third passivation layer 106 can be adjusted so that in combination they serve as anti-reflection coating with respect to a wavelength of electromagnetic radiation that is consistent with a desired functionality of the device 150. The selection of relative thicknesses can be achieved through methods known to those of skill in the art.

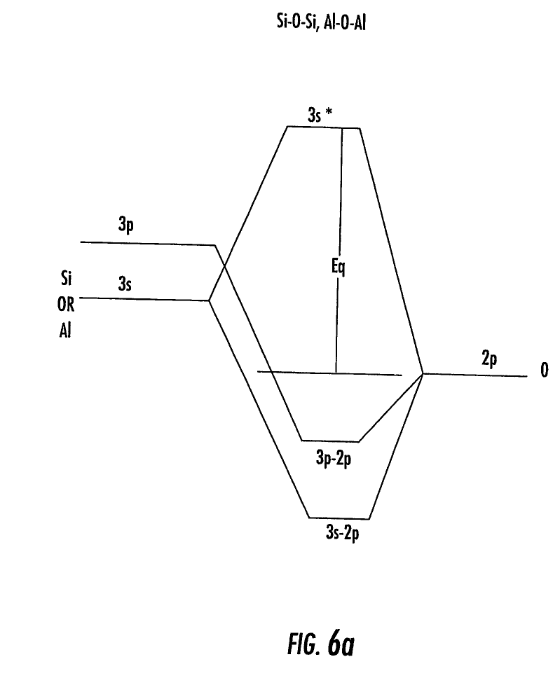

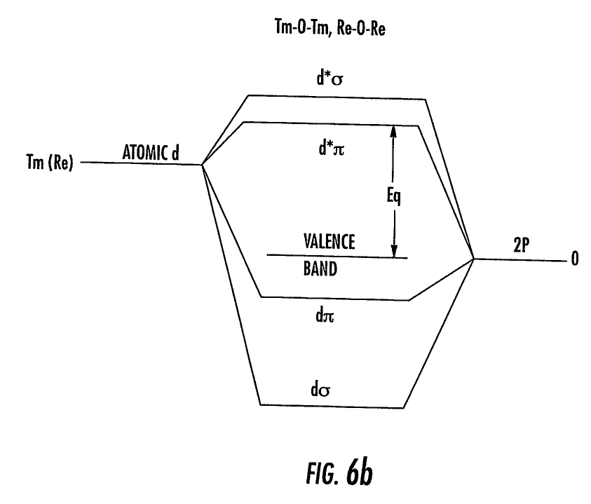

A high electron mobility transistor or HEMT device 250 is shown in FIG. 5a. The HEMT device 250 includes a substrate 203. Various layers of the HEMT device 250 are formed on the substrate 203, including a curried channel semiconductor layer 202, a wide band gap semiconductor confinement layer 201, a second wide band gap semiconductor confinement layer 203, an n-type source 208, an n-type drain 211, a gate electrode 205, a source electrode 207, and a drain electrode 210. An ohmic contact 209 to the substrate 203 and an ohmic contact 206 to the gate electrode 205 are provided. A passivation layer 204 between the n-type drain 211 and the gate electrode 205 and also between the n-type source 208 and the gate electrode 205 is provided. The passivation layer 204 can comprise a dielectric material, such as materials according to the formula (I). The passivation layer 204 can be a thin film, stoichiometric, single-phase complex oxides.

In operation, a positive bias can be applied to the gate electrode 205, through the ohmic contact 206, and the source contact 207 can be held at ground potential through the source electrode 207, which is likewise grounded. A drain contact can be held at a positive potential through application of positive drain bias voltage to the drain electrode 210. The passivation layer 204 can suppress recombination of electrons at the respective portions of surface of the wide band gap semiconductor confinement layer 201, denoted as 201a and 201b, between the source 208 and the drain 211, and the gate electrode 205.

The semiconductor substrate 203, the wide band gap semiconductor confinement layer 201, the buried channel semiconductor layer 202, and certain other layers shown in FIG. 5a can be made of various materials, the selection of which is known to those of skill in the art. For example, the substrate 203 and wide band gap semiconductor confinement layer 201 may be doped n-type Si, and the buried channel semiconductor layer 202 can be an undoped Si,Ge alloy layer. Moreover, the source contact 208 and the drain contact 211 may be heavily doped, e.g., >10¹⁹ cm⁻³ n-type Si.

Alternatively, the semiconductor substrate 203 and wide band gap semiconductor confinement layer 201 may be doped n-type (In,Ga)As or other group III-V alloy semiconductors that can lattice-matched to an InP substrate, and the buried channel semiconductor layer 202 can be an undoped (In,Ga)As alloy layer with approximately 20 percent InAs content. The source contact 208 and the drain contact 211 may be a heavily doped (>10¹⁹ cm⁻³) n-type (In,Ga)As alloy.

As another example, the semiconductor substrate 203 in contact with the buried channel semiconductor layer 202 and the wide band gap semiconductor confinement layer 201 may comprise a doped n-type (In,Ga)As alloy or other alloy semiconductors that are lattice matched to an InP substrate. The curried channel semiconductor layer 202 can be an undoped (In,Ga)As alloy layer with approximately 20 percent InAs content. The source contact 208 and the drain contact 211 can be heavily doped (>10¹⁹ cm⁻³) n-type (In,Ga)As. The substrate 203 may also included an additional semiconductor layer (not shown), such as heavily doped InP that may be in contact with both the doped (In,Ga)As portion of 203, and the substrate layer ohmic contact 209.

In still another example, the semiconductor substrate 203 and the wide band gap semiconductor confinement layer 201 can be a doped n-type (Al,Ga)N alloy, and the buried channel semiconductor layer 202 can be an undoped (Al,Ga)N alloy or GaN. The source contact 208 and the drain contacts 211 can be heavily doped (>10¹⁹ cm⁻³) n-type (Al,Ga)N. The substrate 203 may be a composite layer in which a portion of the substrate 203 adjacent the buried channel semiconductor layer 202 is doped n-type (Al,Ga)N, and a portion of the substrate layer 203 adjacent the substrate ohmic contact 209 is a single or composite semiconductor layer such as GaN or SiC, or a combination thereof. Alternatively, the portion of the substrate layer adjacent the substrate ohmic contact 209 may include an insulating substrate such as single crystal sapphire, e.g., Al₂O₃.

Referring to FIG. 5b, the device 250 further includes a second dielectric layer 212 that is placed between the passivation layer 204 and the gate electrode 205 and a portion of the side band gap semiconductor confinement layer 201. The second dielectric layer can be a dielectric material according to formula (I), or a stacked semiconductor layer comprising either thermally grown, or plasma oxidized native oxide such as silicon oxide, gallium oxide or aluminum oxide according, the selections of which are known to those skilled in the art.

HEMT devices according to embodiments of the present invention may include addition semiconductor layers for improved operation, and/or as may be required for epitaxial growth of the channel structures. The integration of and functionality of these passivation layers may be used in devices described with respect to the examples discussed herein. Additional passivation layers may be fabricated from other generic families of III-V semiconductors including antimonides such as GaSb, III-V ternary antimonide alloys, (Al,Ga)Sb, (In,Ga)Sb, and III-V quaternary alloys, (In,Al,Ga)Sb and the like.

As discussed above, the thin film, stoichiometric, single-phase complex oxides, such as oxides described by formula (I), may have applications that include gate dielectrics and passivation layers for electronic and photonic devices as described herein. Oxide films may be provided that are generally thinner than 15 nm. The thickness of a film can be determined from cross section transmission electron micrographs or by spectroscopic techniques such as thin film interference, and spectroscopic or single wave length ellipsometry. Other methods may also be applied. Single-phase, thin film complex oxides may be provided that can be either non-crystalline (as determined by conventional x-ray or electron diffraction methods, including bright field-dark field imaging, or alternatively nano- or micro-crystalline according to conventional diffraction methods indicated above, but also including other methods such as extend x-ray absorption fine structure spectroscopy, or EXAFS).

With reference to formula (I) and as discussed above, A is a lanthanide rare earth atom and B is a first, second or third row transition metal from group IIIB, IVB or VB, respectively, that are bound to a common oxygen atom. Atoms A and B generally have different atomic d-state energies in the s²dⁿ⁻² configuration. Without wishing to be bound by theory, the limitation for a specific type of stoichiometry, such as defined in formula (I), may result in coupling of both constituent atom atomic-d states through bonding to a common oxygen atom. The limitation may also exclude other possible bonding arrangements in which equal numbers of atoms of a given class, lanthanide rare earth or transition metal, are connected through a common oxygen atom. As one example, this may be achieved in chemically-ordered oxides, which include equal concentrations of these two metal atom constituents, the transition metal and lanthanide rare earth atoms, and in which the oxygen atom coordination is effectively even in character, e.g., four, six or eight, or a mixture thereof, and allowing for small differences in nearest neighbor inter-atomic bond length that may be associated with the film morphology, non-crystalline, or micro- or nano-crystaline. Other bonding arrangements that involve bonding between oxygen atoms and the transition metal and lanthanide rare earth atoms are possible.

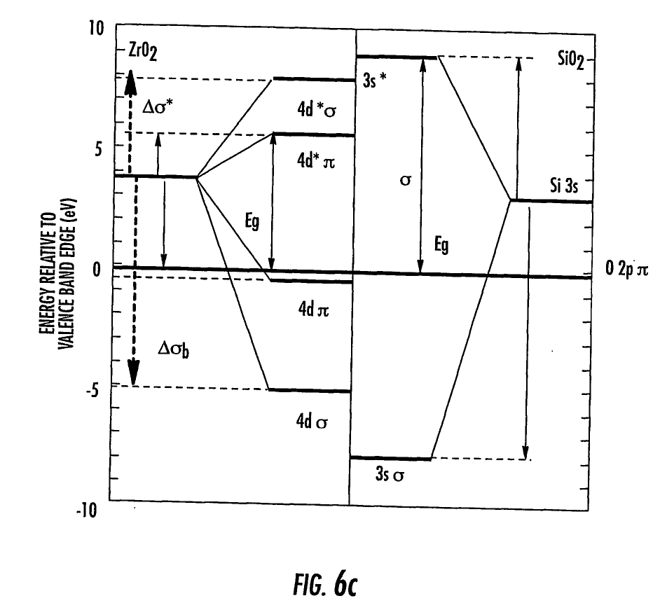

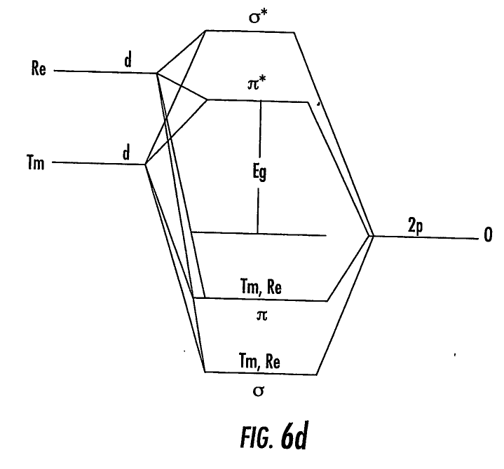

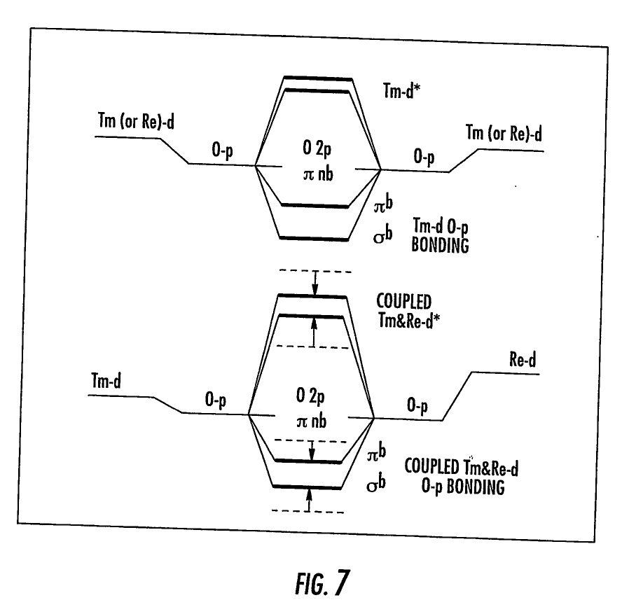

Once again without wishing to be bound by theory, a comparison between thin film stoichiometric complex oxides according to formula (I) and other high-K dielectrics may be made with reference to the electronic structures illustrated in FIGS. 6a to 6d. FIG. 6a is a schematic illustration of the basic element of local bonding, and the resultant band edge electronic structure in SiO₂. Similar bonding prevails in Al₂O₃ as well. As shown in FIG. 6a, the electronic structures consist of local arrangements in which Si and Al atoms, respectively, are connected as next-nearest bonding neighbors through a common oxygen atom. The electronic structure diagram indicates the chemical and symmetry character of the highest lying state in the valence band that determines, for example, the valence band offset energy difference with respect to crystalline Si, or to another semiconductor. This state is pure oxygen atom 2p non-bonding state with π symmetry. The lowest conduction band state is an anti-bonding silicon atom 3s*-state with σ-bonding character.

FIG. 6b schematically illustrates the basic element of local bonding, and the resultant band edge electronic structure, in transition metal and lanthanide rare earth elemental oxides, e.g., the transition metal oxides Y₂O₃, ZrO₂ and Nb₂O₃, and the rare earth lanthanide trivalent oxides including, as an example, Gd₂O₃. The corresponding local bonding group includes transition metal or lanthanide rare earth atoms, denoted as Tm/Re as next nearest neighbors bonded to the same oxygen atom.

The highest lying states of the valence band are depicted in FIG. 6c, which is a schematic illustration of the basic element of local bonding, and the resultant band edge electronic structure in transition metal (lanthanide rare earth) silicate and aluminate alloys in the low concentration alloy range. For these alloys there are three types of local bonding, denoted schematically as Si—O—Tm(Re), Si—O—Si and Tm(Re)—O—Tm(Re). The bonding arrangements vary with alloy content, and assuming chemically-ordered bonding at the compound silicate phase with the highest SiO₂ concentrations corresponding to as examples, (TmO₂)_{0.5}(SiO₂)_{0.5} for group IVB Tm silicates where Tm=Zr and Hf, and (Tm₂O₃)_{0.33}(SiO₂)_{0.67} for group Tm (and also for trivalent lanthanide Re) silicates, in the concentration range from SiO₂ to these compositions there are Si—O—Si and Si—O—Tm. For this alloy regime, which may be of interest for technology applications where Hf silicates are the materials of choice, the lowest conduction band states have been shown to be at the same energy relative to the conduction band of silicon as for HfO₂ as represented schematically in a comparison between FIGS. 6a to 6c.

FIG. 6d is a schematic illustration of the basic element of local bonding, and the resultant electronic structure that may be present in the thin film, stoichiometric complex oxides according to formula (I). For this case, atomic d-states of the respective Re and Tm with the same bonding symmetry, either σ or π, interact with each other through bonding to the same oxygen atom with a compatible bonding-symmetry, either σ or π, according the symmetry of the d-states, respectively, σ or π, in bonding groups represented schematically by Re—O—Tm. The resulting valence band states immediately below the top of the valence band defined by the oxygen 2p non-bonding p states, are energies that are different from those of Tm—O—Tm and Re—O—Re and complementary conduction states, particularly the state that the defines the lowest band gap, and the conduction band offset energy with respect to Si and other semiconductors is different as well.

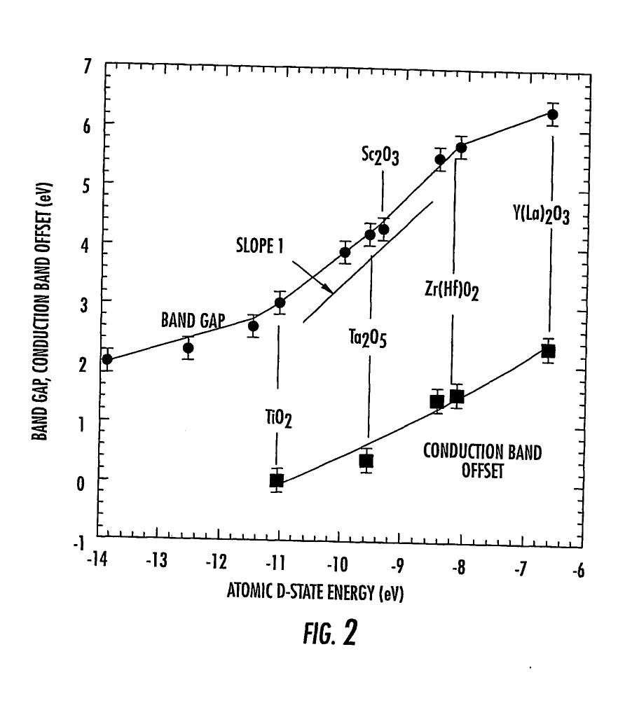

Returning to FIGS. 6a to 6c, the band gaps and offset energies of the prior art gate dielectric and passivating oxides will now be discussed. The band gaps and band offset energies for the dielectrics of FIG. 6a may result from bonding between atomic 3s and 3p states of Si or Al, and oxygen atom 2p states, and as such give rise to large band gaps (e.g., greater than 8 eV), intermediate range dielectric constants (e.g., between 3.9 (for SiO₂) to about 10-12), as well as relative large valence and conduction band offset energies (e.g., greater than approximately 2 eV). The lowest conduction band states in SiO₂ may be predominantly 3s-like, whereas, the lowest bonding states in Al₂O₃ can include a larger mixing of 3p due to the increased bond ionicity, approximately 57% on the Pauling scale for Al₂O₃ in contrast to ˜45% on the same scale for SiO₂. The dielectrics having electronic states such as those shown in FIG. 6b span a wide range of band gaps, dielectric constants and band offset energies where, as noted herein, and shown in FIG. 2, the band gap and band offset energies can scale with the highest occupied atomic d-state energies of the respective transition metal and lanthanide rare earth lanthanide atoms in the s²dⁿ⁻² configuration. There may also be an additional, but weaker scaling of the dielectric constant, K, with band gap; K typically increases as the band gap decreases. The situation for the silicate and aluminate alloys may be more complex, but understood for dielectrics of according to the diagram of FIG. 6c. The band gaps scale with alloy composition, increasing as either the SiO₂ or Al₂O₃ alloy fraction is increased, but the conduction band offset energies in the alloys with respect to Si and other semiconductors may be determined solely by the atomic d-state energies of the transition or rare earth atoms in much the same way as they are in the respective transition metal or rare earth elemental oxides. On the other hand, the valence band offset energies with respect to silicon and other semiconductors may be increased as the SiO₂ or Al₂O₃ content can be increased.

Dielectrics according to the schematic diagram of FIG. 6d may be qualitatively and quantitatively different than dielectric materials according to the schematic diagrams of FIGS. 6a to 6c. Because of d-state quantum mechanical wave function mixing through bonding of different transition metal and lanthanide rare earth atoms to a common oxygen atom, the valence band π-bonding states may be changed in energy, resulting in increases in both the band gaps of these complex stoichiometric oxides and their conduction band offset energies with respect to silicon and other semiconductors. Choices of the different combinations of transition metal and rare earth atoms bonded to the same oxygen atom may effect the resulting properties of the material. For example, in general, the larger the difference in the atomic d-states of these atoms the larger the increase in band with respect to the smaller band gap member of the pair. As a general example, the lanthanide rare earth atomic 4d-state energies are nominally −5.6 to −6 eV with respect to vacuum; the lowest d-state energy if the −11 eV for the 3d state of Ti, with Nb and Ta following close behind with respective energies of −10 eV and −9.6 eV. Taking the 5d-state energy of an average lanthanide rare earth atom at −6.8 eV, the respective differences for a ReTi2O7 complex oxide, a ReNbO4 complex oxide and a ReTaO4 complex oxides may be respectively, about 4.2 eV, 3.2 eV and 2.8 eV.

In some instances, the band gap shift can be estimated in context of a virtual crystal approximation such that the complex oxide displays properties that are a simple, or weighted averages of the end member oxides. Based on the overlap integral differences, valence band states are at intermediate energies with respect to the corresponding elemental oxides states, thereby increasing the energy of the lowest conduction band state with respect to the transition metal oxide atom. An example of virtual crystal approximation scaling is illustrated by comparisons between GdScO₃ and ZrO₂, where the onsets of strong absorption occur respectively at 5.8 and 5.7 eV, demonstrating that that GdScO₃ with 5d atomic states for the lanthanide rare earth atom Gd, and 3d atomic states for the transition metal atom Sc, has a band gap characteristic of a 4d transition metal oxide with a 4d-state energy equal to the average of the 3d- and 5d-state energies of Sc and Gd, respectively. The average atomic d-state energy in GdScO₃ is equal to approximately one-half of the sum of −6.6 eV for the 5d-state of Gd and −9.4 eV for the 3d-state of Sc, or −8 eV. This value is approximately equal the atomic 4 d-state energy of Zr, which is −8.13 eV.

The band edge electronic structure of a transition metal or rare earth elemental oxide and a complex oxide according to formula (I), e.g. a complex oxide including a group IIIB transition metal oxide such as Sc2O3, and lanthanide group rare earth oxide such as Gd₂O₃, is illustrated schematically in FIG. 7. Specific examples of complex oxides identified by formula (I) include, but are not limited to thin film i) GdScO₃, DyScO₃, SmScO₃, and other trivalent lanthanide rare earth oxides in combination with the group IIIB transition metal oxide, Sc₂O₃, ii) Gd₂Ti₂O₇, Dy₂Ti₂O₇, Sm₂Ti₂O₇ and other trivalent lanthanide rare earth oxides in combination with the group IVB transition metal oxide TiO₂, iii) GdNbO₄, DyNbO₄, SMnNbO₄ and other trivalent lanthanide rare earth oxides in combination with the group VB transition metal oxide Nb₂O₃, and iv) GdTaO₄, DyTaO₄, SmTaO₄ and other trivalent lanthanide rare earth oxides in combination with the group VB transition metal oxide Ta₂O₅.

Various tests may be used to characterize thin film oxides. One test involves studying the thin film sample by x-ray absorption spectroscopy, sometimes also called near edge x-ray absorption fine structure spectroscopy, either XAS, or NEXAFS, respectively. The specific test includes a study of three different absorptions which occur in 100 to 600 electron volt range of x-ray energies. Mono-energetic or monochromatic beams of x-rays in this energy range are readily available at synchrotron light sources at many different synchrotron sites, including Brookhaven National Laboratory and Stanford University in the United States, and these measurements can be performed at these or similar sites. The tests are described by a specific example. However, it should be understood that the tests may be extended and/or comparisons or extrapolations may be made to other complex oxides. For example, if the complex oxide is GdScO₃, the absorption spectrum can be plotted as normalized absorption in arbitrary units as a function of the photon energy of the X-rays in eV, for transitions from i) spin orbit split Sc 2p atomic states to symmetry split Sc 3d atomic states at a threshold of approximately 400 eV, ii) spin orbit split Gd 4p atomic states to symmetry split Gd 5d atomic states at a threshold of approximately 250 eV, and iii) the oxygen atom K₁ edge with at a threshold energy of approximately 530 eV. A spectral width of interest for the Sc 2p transitions can be approximately 10 eV, for the Gd 4p transitions, or approximately 40 eV because of the larger spin orbit splitting, ˜30 eV in Gd as compared to 4-5 eV in Sc, and ˜15 eV for the 0 K₁ edge. Two pairs of symmetry split transitions to 3d states may be observed for 5c, whereas these pairs of states may be evident, but not readily separable in the broadened 5d spectral features for Gd. As a result of the mixing, the complex oxide is expected to display evidence for no more than two d-states in the O K₁ edge, a narrower one with more 3d character, and a broader one with more 5d character, and at an energy separation of approximately 3.5 to 4 eV. The occurrence of four d-state features in an O K₁ spectrum, each mimicking what is observed in the oxygen K₁ spectrum of the respective constituent oxides, may indicate that the material is not a chemically-ordered, stoichiometric complex oxide. However, the occurrence of three d-state features in an O K₁ spectrum is indicative of atomic d-state mixing, but with different local symmetry conditions applying.

In addition to having band gaps and conduction band offset energies that may be increased as compared to the respective transition metal oxides, Sc₂O₃, TiO₂, Nb₂O₅ and Ta₂O₅, oxides according to formula (I) may have relatively high values of K, e.g., intermediate between those of the respective transition metal and rare earth elemental oxides, but generally closer in value to those of the transition metal oxides.

Accordingly, various complex oxides may be provided that can have different properties compared with their elemental oxide constituents (e.g., oxides formed from either A or B in formula (I)). For example, certain elemental oxides may be strongly hydrophilic, such as can be characteristic of the lanthanide rare earth oxides. Certain elemental oxides may also display significant ionic conductivity, such as the group IVB oxides, most notably ZrO₂. In contrast, oxides according to formula (I) may result in reduced hydrophilic and ionic conductivity as compared with certain elemental oxides.

Embodiments according to the present invention will be described in more detail with reference to the following non-limiting examples and the accompanying diagrams.

### EXAMPLE 1

A field effect transistor is formed according to the following procedure. Radio frequency remote plasma assisted oxidation using oxygen as the source gas is employed to form an SiO₂ insulating layer on a Si-containing substrate such as Si, SiC or a (Si,Ge) alloy. The above process is carried out at 300° C. A thin film, stoichiometric, single-phase complex oxide according to formula (I) is formed on the insulating layer via a radio frequency remote plasma enhanced CVD deposition carried out at 300° C. The structure is then exposed to a post deposition rapid thermal anneal in an inert, non-oxidizing ambient such as helium or argon for e.g., 30 seconds at 900° C.

The resulting field effect transistor has an SiO₂ insulating layer with a thickness of less than 0.5 nm (i.e., 5 Å) and a gate insulating layer physical thickness of more than 2.0 nm (i.e., 20 Å), that, in combination with the interfacial SiO₂ layer is chosen to meet the targeted EOT, e.g., in the range of 0.7 nm to 1.5 nm.

### EXAMPLE 2

A field effect transistor is formed according to the procedure set forth in Example 1 with the following modifications. The substrate is exposed to an N₂ remote plasma to allow for the formation of silicon-nitrogen bonding at the surface of the silicon substrate. The other layers are formed in the manner previously described.

### EXAMPLE 3

A field effect transistor is formed according to the procedure set forth in Example 1 with the following modifications. A remote plasma assisted oxidation using N₂O instead of O₂ is employed to form a thin SiO₂ layer with silicon-nitrogen boding at the silicon substrate.

### EXAMPLE 4

The devices described in Examples 1, 2 and 3, wherein the Ge, (Si,Ge) alloys, GaN, (Al,Ga)N and (In,Ga)N and other compound III-V semiconductors alloys, such as GaAs, (Al,Ga)As, InP, (In,Ga)As and the like are substituted for c Si. are employed as the semiconductor substrate layer which includes the channel. When compound III-V semiconductors other than GaN and (Al,GaN) or (In,Ga)N are used as the substrate, these substrate layers may include a sacrificial semiconductor layer such as Si or GaN nitride, adjusted in thickness to be converted to a silicon or gallium oxide during the oxidation steps of Examples 1, 2 and 3, and to prevent oxidation of the underlying substrates which could result in the formation of elemental arsenic or phosphorus, or their oxides.

### EXAMPLE 5

A silicon based HEMT device, in which the channel layer is a (Si,Ge) alloy, the confining layers are Si, and in which the passivation layer covers the portions of the device between the source and gate electrode, and the drain and the gate electrode.

### EXAMPLE 6

A silicon based HEMT device is provided, in which the channel layer is a (Si,Ge) alloy, the confining layers are Si, and in which the passivation layer covers the portions of the device between the source and gate electrode, and the drain and the gate electrode, and in which there is an additional interfacial oxide, or nitrided oxide layer that extends over the entire surface of the device, including the gate electrode region. The passivation layer covers this layer between the source and gate electrode, and the drain and the gate electrode, and the gate electrode covers this layer as well.

### EXAMPLE 7

A HEMT device based on III-V alloys that are lattice matched to InP. This includes in one embodiment, an (In,Ga)As channel and confining and substrate lattice matched alloys that are also lattice matched to InP. The passivation layer comprises at least one constituent that is a thin film oxide according to formula (I), and covers the portions of the device between the source and gate electrode, and the drain and the gate electrode. In a second embodiment, the first constituent of the multi-layer passivation film, also extends below the gate electrode, and is covered completely by the gate electrode.

### EXAMPLE 8

A HEMT device based on III-V alloys that are lattice matched to GaN. This can include a GaN channel and confining and substrate layers are lattice matched alloys with wider band gap, as (Al,Ga)N. The passivation layer comprises at least one constituent that is a thin film oxide according to formula (I), and covers the portions of the device between the source and gate electrode, and the drain and the gate electrode. Alternatively, the first constituent of the multi-layer passivation film, also extends below the gate electrode, and is covered completely by the gate electrode.

### EXAMPLE 9

A HEMT device based on group III-V antimonides. This can includes a HEMT device in which a GaSb layer is the channel and confining and substrate layers, which are lattice matched alloys with wider band gap, as (Al,Ga)Sb. The passivation layer comprises at least one constituent according to formula (I), and covers the portions of the device between the source and gate electrode, and the drain and the gate electrode. In another example, the first constituent of the multi-layer passivation film, also extends below the gate electrode, and is covered completely by the gate electrode.

### EXAMPLE 10

A first photovoltaic example in which the substrate material is doped n-type Si, either single crystal, polycrystalline or microcrystalline, and the top layer of the device is doped p-type Si, again either single crystal, polycrystalline or microcrystalline. An ohmic contact is made to the entire bottom surface of the substrate material, and the top surface ohmic contact is either in a ring geometry that is at the perimeter of a circular device, an inter-digitated or comb-like contact that is customized to the device geometry, e.g., either square or rectangular, or of another design that is consistent with maximizing the surface exposed to radiation, and minimizing any parasitic series resistance that derives from the limit coverage of the top surface. The same geometry can be employed with compound semiconductors, e.g., SiC, GaN, GaAs, InAs, and the like, and their ternary or quaternary alloys. The conductivity types of the top and substrate layers can also be reversed.

With respect to the above examples, the devices describe may include a thin film, stoichiometric, single-phase complex oxide according to formula (I) as one consituent of a surface passivation film. The surface passivation film layer may also provide an anti-reflection function as well. Various other dielectric components of semiconductor devices can be fabricated using the complex oxide according to formula (I), including a capacitor dielectric or an isolation trench.

In the drawings and specification, there have been disclosed embodiments of the invention and, although specific terms are employed, they are used in a generic and descriptive sense only and not for purposes of limitation, the scope of the invention being set forth in the following claims.

That which is claimed:

1. A semiconductor device comprising:
a semiconductor substrate;
a first oxide layer on the semiconductor substrate, the first oxide layer comprising an element from the semiconductor substrate;
a second oxide layer on the first oxide layer opposite the semiconductor substrate, the second oxide layer comprising a stoichiometric, single-phase complex oxide represented by the formula:
AₕBⱼOₖ, or equivalently (AₘOₙ)ₐ(B_{q}Oᵣ)_{b}
in which the elemental oxide components, (AₘOₙ) and (B_{q}Oᵣ) are combined so that h=j or, equivalently, ma=bq, and a, b, h, j, k, m, n, q and r are non-zero integers; and wherein:
A is an element of the lanthanide rare earth elements of the periodic table or the trivalent elements from cerium to lutetium; and
B is an element of the transition metal elements of groups IIIB, IVB or VB of the periodic table.

2. A device according to claim 1 wherein the second oxide layer has a thickness of less than 15 nm.

3. A device according to claim 1 wherein the second oxide layer has a band gap of greater than about 5.5 eV.

4. A device according to claim 1 wherein the second oxide layer has a conduction band offset energy of greater than 1.5 eV.

5. A device according to claim 1 wherein the second oxide layer has an equivalent oxide thickness (EOT) of about 0.5 to about 1.6 nm.

6. A device according to claim 1 wherein B is an element with 3d, 4d or 5d electrons available for bonding to oxygen, and wherein A is an element in which one 5d electron is available for bonding.

7. A device according to claim 1, wherein B is scandium, titanium, tantalum or niobium.

8. A device according to claim 1, wherein B is scandium, titanium, tantalum, or niobium (Nb) and wherein A is trivalent gadolinum, praseodynium or lutetium.

9. A device according to claim 1, wherein B is scandium, titanium, tantalum or niobium and wherein A is cerium, nedoymnium, promethium, samarium, europium, terbium, dysprosium, holmium, erbium, thulium, or ytterbium.

10. A device according to claim 1, wherein the substrate comprises a material selected from the group consisting of a Group III-V binary alloy, a Group III-V quaternary alloy, a Group III-nitride alloy, and combinations thereof.

11. A device according to claim 1, wherein the substrate comprises a Group III-V binary alloy selected from the group consisting of (Ga,Al)As, (In,Ga)As, and combinations thereof.

12. A device according to claim 1, wherein the substrate comprises a Group III-V quaternary alloy comprising (Ga,In)(As,P).

13. A device according to claim 1, wherein the substrate comprises a Group III-nitride alloy selected from the group consisting of (Ga,Al)N, (Ga,In)N, (Al,In)N, (Ga,Al,In)N, and combinations thereof.

14. A device according to claim 1, wherein the substrate comprises a material selected from the group consisting of silicon (Si), germanium (Ge), silicon carbide (SiC), gallium nitride (GaN), gallium arsenide (GaAs), and combinations thereof.

15. A device according to claim 1, wherein the substrate is a semiconductor-on-insulator (SOI) substrate.

16. A device according to claim 1, wherein the first oxide layer comprises a nitrided silicon dioxide.

17. A device according to claim 16, wherein the first oxide layer contributes less than about 0.5 nm of oxide-equivalent capacitance to said field effect transistor.

18. A device according to claim 1, wherein the device comprises a field effect transistor.

19. A device according to claim 1, wherein the device comprises a photovoltaic device.

20. A device according to claim 1, wherein the device comprises a high electron mobility transistor.

21. A method of forming a semiconductor device comprising:
providing a semiconductor substrate;
forming a first oxide layer on the semiconductor substrate.
forming a second oxide layer on the first oxide layer opposite the semiconductor substrate, the second oxide layer comprising a stoichiometric, single-phase, complex oxide represented by the formula:
AₕBⱼOₖ, or equivalently (AₘOₙ)ₐ(B_{q}Oᵣ)_{b}
in which the elemental oxide components, (AₘOₙ) and (B_{q}Oᵣ) are combined so that h=j or, equivalently, ma=bq, and a, b, h, j, k, m, n, q and r are non-zero integers; and wherein:
A is an element of the lanthanide rare earth elements of the periodic table or the trivalent elements from cerium to lutetium; and
B is an element of the transition metal elements of groups IIIB, IVB or VB of the periodic table.

22. A method according to claim 21, further comprising:
exposing the substrate to one or more gaseous sources comprising elements A, B, and oxygen such that one or more gaseous sources react to form the second oxide layer.

23. A method according to claim 22, wherein the one or more gaseous sources comprise an amount of oxygen sufficient to substantially oxidize elements A and B.

24. A method according to claim 21, wherein the step of forming a second oxide layer is performed by a remote plasma-enhanced chemical vapor deposition process.

25. A method according to claim 24, further comprising:
exposing a gaseous source comprising oxygen and a rare-gas element to radio-frequency plasma-excitation or microwave frequency plasma-excitation;
combining the gaseous source comprising oxygen and a rare-gas element with a gaseous source comprising element A and element B; and
exposing the substrate to the combined gaseous source.

26. A method according to claim 25, wherein the rare gas element is selected from the group consisting of argon and helium.

27. A method according to claim 21, wherein B is an element with 3d, 4d or 5d electrons available for bonding to oxygen, and wherein A is an element in which one 5d electron is available for bonding as in trivalent ions.

28. A method according to claim 21, wherein B is either scandium, titanium, tantalum or niobium.

29. A method according to claim 21, wherein the step of forming a second oxide layer is performed by an atomic layer absorption process.

30. A method according to claim 21, wherein the device comprises a field effect transistor.

31. A method according to claim 21, wherein the device comprises a photovoltaic device.

32. A method according to claim 21, wherein the device comprises a high electron mobility transistor.
